(19) United States
(12) Patent Application Publication
(10) Pub. No.: US 2025/0167040 A1
(43) Pub. Date: May 22, 2025

(54) LIFTING MECHANISM AND SUBSTRATE PROCESSING APPARATUS

(71) Applicant: Tokyo Electron Limited, Tokyo (JP)

(72) Inventor: Manabu HONMA, Oshu City (JP)

(21) Appl. No.: 18/945,835

(22) Filed: Nov. 13, 2024

(30) Foreign Application Priority Data
Nov. 22, 2023 (JP) 2023-197975

(51) Int. Cl. H01L 21/687; B25J 19/00

(52) U.S. Cl. CPC H01L 21/68792; B25J 19/0054

(57) ABSTRACT

A lifting mechanism for raising or lowering a substrate holder configured to hold a plurality of substrates in a shelf-like manner, includes a support configured to support the substrate holder, and a multi-joint arm having a tip connected to the support to raise or lower the support.

### CROSS-REFERENCE TO RELATED APPLICATION

This application is based upon and claims the benefit of priority from Japanese Patent Application No. 2023-197975, filed on Nov. 22, 2023, the entire contents of which are incorporated herein by reference.

### TECHNICAL FIELD

The present disclosure relates to a lifting mechanism and a substrate processing apparatus.

### BACKGROUND

There is known an apparatus in which a substrate holder for holding a plurality of substrates is loaded into a processing container where the substrates are processed collectively (see, for example, Patent Documents 1 and 2). The substrate holder is loaded into the processing container by, for example, a lifting mechanism with a ball screw or bellows.

### PRIOR ART DOCUMENTS

### Patent Documents

Patent Document 1: Japanese Laid-Open Patent Publication No. 2012-169367

Patent Document 2: Japanese Laid-Open Patent Publication No. 2000-286324

### SUMMARY

According to one embodiment of the present disclosure, a lifting mechanism for raising or lowering a substrate holder configured to hold a plurality of substrates in a shelf-like manner, includes a support configured to support the substrate holder, and a multi-joint arm having a tip connected to the support to raise or lower the support.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view (1) illustrating a substrate processing apparatus according to a first embodiment.

FIG. 2 is a longitudinal cross-sectional view (2) illustrating the substrate processing apparatus according to the first embodiment.

FIG. 3 is a longitudinal cross-sectional view (3) illustrating the substrate processing apparatus according to the first embodiment.

FIG. 4 is a cross-sectional view taken along line IV-IV in FIG. 3, as seen in the direction of arrows.

FIG. 5 is a longitudinal cross-sectional view (1) illustrating a substrate processing apparatus according to a second embodiment.

FIG. 6 is a longitudinal cross-sectional view (2) illustrating the substrate processing apparatus according to the second embodiment.

FIG. 7 is a longitudinal cross-sectional view (1) illustrating a substrate processing apparatus according to a third embodiment.

FIG. 8 is a longitudinal cross-sectional view (2) illustrating the substrate processing apparatus according to the third embodiment.

### DETAILED DESCRIPTION

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

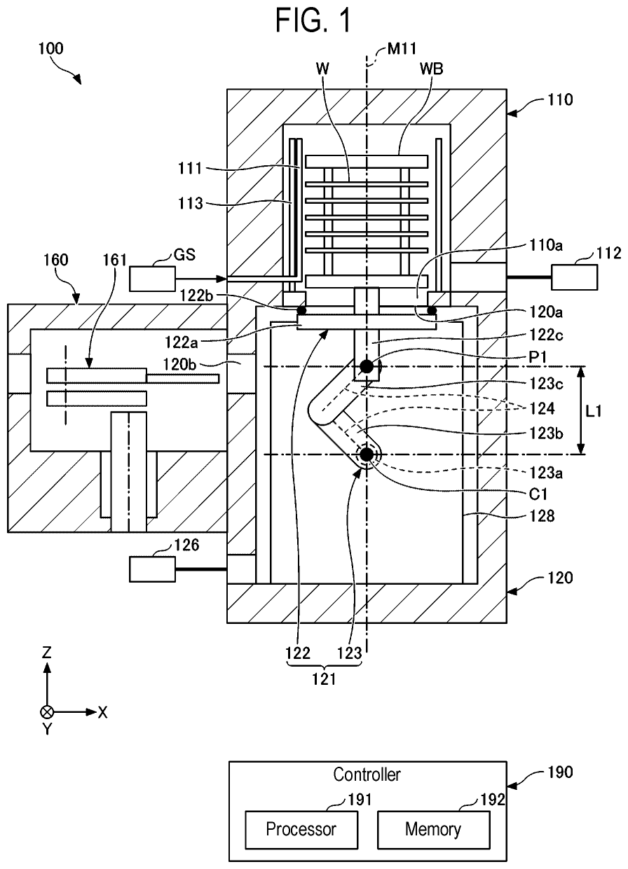

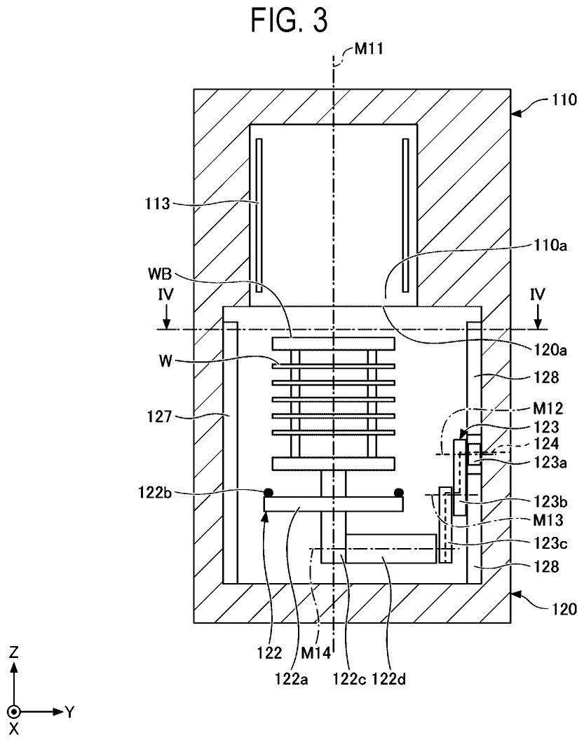

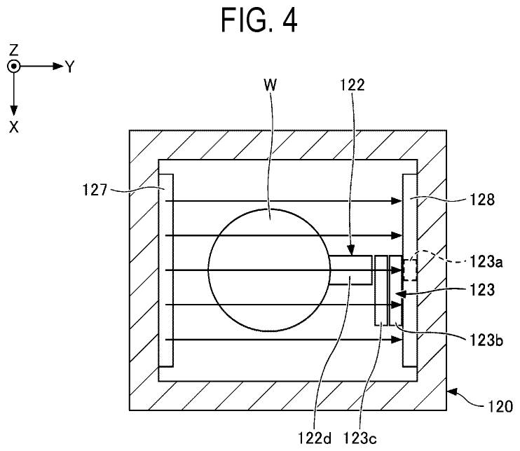

A substrate processing apparatus 100 according to a first embodiment will be described with reference to FIGS. 1 to 4. The substrate processing apparatus 100 includes a processing chamber 110, a load lock chamber 120, a substrate transfer chamber 160, and a controller 190.

An interior of the processing chamber 110 may be depressurized. A substrate holder WB may be accommodated in the interior of the processing chamber 110. The substrate holder WB holds a plurality of substrates W in a shelf-like manner. Five substrates are illustrated in FIGS. 1 to 3, but the number of substrates W is not limited. The plurality of substrates W held by the substrate holder WB are processed collectively in the interior of the processing chamber 110. A loading/unloading port 110a is provided at a bottom of the processing chamber 110 to load and unload the substrate holder WB therethrough. The processing chamber 110 is provided with a gas nozzle 111, an exhaust device 112, and a heater 113.

The gas nozzle 111 is provided around the substrate holder WB located inside the processing chamber 110. The gas nozzle 111 discharges a processing gas from a gas source GS toward the substrate holder WB and the substrates W in the vicinity of the substrate holder WB located inside the processing chamber 110. The processing gas is selected according to the type of processing. One gas nozzle 111 may be provided, or two or more gas nozzles 111 may be provided.

The exhaust device 112 exhausts the processing chamber 110 to depressurize the interior of the processing chamber 110. The exhaust device 112 includes, for example, a vacuum pump and a pressure control valve. The exhaust device 112 controls the interior of the processing chamber 110 to have a desired pressure by adjusting an opening degree of the pressure control valve while evacuating the interior of the processing chamber 110 by the vacuum pump.

The heater 113 is provided inside the processing chamber 110. The heater 113 may be provided around the substrate holder WB, which is located inside the processing chamber 110. The heater 113 heats the substrate holder WB and the substrates W to a desired temperature in the vicinity of the substrate holder WB located inside the processing chamber 110.

The load lock chamber 120 is located below the processing chamber 110. An interior of the load lock chamber 120 may be depressurized. The substrate holder WB may be accommodated in the interior of the load lock chamber 120. A loading/unloading port 120a is provided at a top of the load lock chamber 120 to load and unload the substrate holder WB therethrough. The interior of the load lock chamber 120 is in communication with the interior of the processing chamber 110 via the loading/unloading port 110a and the loading/unloading port 120a. The substrate holder WB is loaded from the load lock chamber 120 into the processing chamber 110 via the loading/unloading ports 110a and 120a. The substrate holder WB is unloaded from the processing chamber 110 into the load lock chamber 120 via the loading/unloading ports 110a and 120a. The substrates W are loaded into and unloaded from the substrate holder WB inside the load lock chamber 120. A loading/unloading port 120b through which the substrates W are loaded and unloaded is provided on a sidewall of the load lock chamber 120 in a negative X-direction. The substrates W are loaded from the substrate transfer chamber 160 into the load lock chamber 120 via the loading/unloading port 120b. The substrates W are unloaded from the load lock chamber 120 into the substrate transfer chamber 160 via the loading/unloading port 120b. The load lock chamber 120 is provided with a lifting mechanism 121, an exhaust device 126, a cooling gas supplier 127, and an exhaust duct 128.

The lifting mechanism 121 raises or lowers the substrate holder WB between the processing chamber 110 and the load lock chamber 120. The lifting mechanism 121 includes a support 122 and a multi-joint arm 123.

The support 122 supports the substrate holder WB. The support 122 includes a lid 122a, a sealing member 122b, a rotary shaft 122c, and a support arm 122d. In a state where the substrate holder WB is positioned in the processing chamber 110 (FIG. 1), the lid 122a hermetically seals the loading/unloading port 110a and the loading/unloading port 120a using the sealing member 122b. As a result, the interior of the processing chamber 110 is hermetically sealed. The sealing member 122b is, for example, an O-ring. A through-hole is provided in the center of the lid 122a so as to vertically penetrate the lid 122a. The rotary shaft 122c is inserted into the through-hole. A gap between the lid 122a and the rotary shaft 122c is sealed by a magnetic fluid seal. The rotary shaft 122c rotatably supports the substrate holder WB around a vertical axis M11. The support arm 122d is connected to the bottom of the rotary shaft 122c. The support arm 122d supports the rotary shaft 122c.

The multi-joint arm 123 may be a vertical multi-joint arm. In this case, since torque is constantly applied to the joint, gear backlash is canceled out to improve positioning accuracy. A base of the multi-joint arm 123 is fixed to the sidewall of the load lock chamber 120 in a positive Y-direction, and a tip of the multi-joint arm 123 is connected to the support arm 122d. The multi-joint arm 123 pivots about the base thereof as a pivot center C1, thereby raising or lowering the support 122. The multi-joint arm 123 loads the substrate holder WB from the load lock chamber 120 into the processing chamber 110 by raising the support 122. The multi-joint arm 123 unloads the substrate holder WB from the processing chamber 110 into the load lock chamber 120 by lowering the support 122.

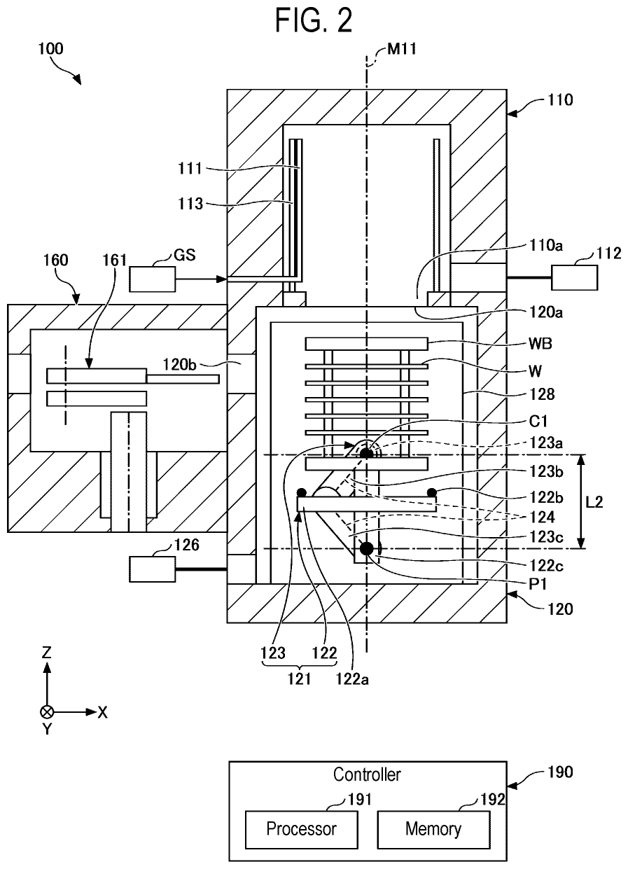

The pivot center C1 of the multi-joint arm 123 may be located at a midpoint of a stroke of the multi-joint arm 123. In this case, a length of each of arms constituting the multi-joint arm 123 and the number of arms may be minimized. For example, as illustrated in FIG. 1, a vertical length between the pivot center C1 of the multi-joint arm 123 and a tip position P1 of the multi-joint arm 123 when the substrate holder WB is in the processing chamber 110 is denoted as L1. For example, as illustrated in FIG. 2, the vertical length between the pivot center C1 of the multi-joint arm 123 and the tip position P1 of the multi-joint arm 123 when the substrate holder WB is in the load lock chamber 120 is denoted as L2. At this time, L1 and L2 may be equal to each other.

The multi-joint arm 123 may include an internal coolant flow path 124 through which a coolant circulates. In this case, the multi-joint arm 123 may dissipate heat even under a vacuum atmosphere, which makes it possible to maintain the positioning accuracy.

The multi-joint arm 123 includes a base end 123a, a first arm 123b, and a second arm 123c.

The base end 123a is fixed to the sidewall of the load lock chamber 120 in the positive Y-direction. The base end 123a may be positioned at the midpoint of the stroke of the multi-joint arm 123. In this case, the length of each of the arms constituting the multi-joint arm 123 and the number of arms may be minimized. The first arm 123b is rotatable relative to the base end 123a about a rotation axis M12. The second arm 123c is rotatable relative to the first arm 123b about a rotation axis M13 and is also rotatable relative to the support arm 122d about a rotation axis M14. The multi-joint arm 123 raises or lowers the substrate holder WB between a position inside the processing chamber 110 (FIG. 1) and a position inside the load lock chamber 120 (FIG. 2) by rotating the first arm 123b and the second arm 123c independently of each other.

The multi-joint arm 123 may have an internal space that is hermetically isolated from an internal atmosphere of the load lock chamber 120 by a magnetic fluid seal or the like. In this case, mechanical components of the multi-joint arm 123 may be arranged in the internal space hermetically isolated from the internal atmosphere of the load lock chamber 120. This may suppress generation of dusts when raising or lowering the substrate holder WB. The internal space of the multi-joint arm 123 may accommodate a plurality of motors equipped with deceleration gears and cables for driving the motors. These motors equipped with the deceleration gears rotate the arms of the multi-joint arm 123 independently of each other. The internal space of the multi-joint arm 123 may be set to atmospheric pressure.

The exhaust device 126 exhausts the interior of the load lock chamber 120, thereby depressurizing the interior of the load lock chamber 120. The exhaust device 126 includes, for example, a vacuum pump and a pressure control valve. The exhaust device 126 controls the interior of the load lock chamber 120 to have a desired pressure by adjusting an opening degree of the pressure control valve while evacuating the interior of the load lock chamber 120 by the vacuum pump.

A cooling gas supplier 127 is provided inside the load lock chamber 120. The cooling gas supplier 127 is attached to the sidewall (second sidewall) of the load lock chamber 120 in the negative Y-direction. The cooling gas supplier 127 is provided to face the substrate holder WB inside the load lock chamber 120. The cooling gas supplier 127 discharges a cooling gas toward the substrate holder WB and the substrates W inside the load lock chamber 120. The cooling gas cools the substrate holder WB and the substrates W inside the load lock chamber 120. Examples of the cooling gas may include a nitrogen gas, an argon gas, and a clean dry air. The cooling gas supplier 127 may be provided in an area which covers an area from the bottom to the top of the substrate holder WB in the vertical direction inside the load lock chamber 120. This makes it possible to efficiently discharge the cooling gas over all the substrates W held by the substrate holder WB. The cooling gas supplier 127 may also be provided in an area which covers an area from one end to the other end of the substrates W held by the substrate holder WB in the X-axis direction inside the load lock chamber 120. This makes it possible to discharge the cooling gas toward each substrate W held by the substrate holder WB with high in-plane uniformity. The cooling gas supplier 127 may be provided over the entire surface of the sidewall of the load lock chamber 120 in the negative Y-direction.

The exhaust duct 128 is provided inside the load lock chamber 120. The exhaust duct 128 is attached to the sidewall (first sidewall) of the load lock chamber 120 in the positive Y-direction. The exhaust duct 128 is positioned to face the cooling gas supplier 127 across the substrate holder WB inside the load lock chamber 120. The exhaust duct 128 suction-exhausts the heated high-temperature atmosphere due to the substrate holder WB and the substrates W inside the load lock chamber 120. As a result, the substrate holder WB and the substrates W inside the load lock chamber 120 may be cooled. The exhaust duct 128 may be provided in an area which covers the area from the bottom to the top of the substrate holder WB in the vertical direction inside the load lock chamber 120. The exhaust duct 128 may also be provided in the area which covers from one end to the other end of the substrates W held by the substrate holder WB in the X-axis direction inside the load lock chamber 120. Since only the base end 123a of the multi-joint arm 123 is fixed to the sidewall of the load lock chamber 120 in the positive Y-direction, the exhaust duct 128 may be provided over the entire surface of the sidewall of the load lock chamber 120 in the positive Y-direction except the position where the base end 123a is fixed. In this case, since an airflow may be formed across the entire surface of the substrates W from the cooling gas supplier 127 toward the exhaust duct 128, the cooling efficiency of the substrates W is improved.

The substrate transfer chamber 160 is connected to the side of the load lock chamber 120 in the negative X-direction. An interior of the substrate transfer chamber 160 may be depressurized. The substrate transfer chamber 160 is provided with a substrate transfer robot 161. The substrate transfer chamber 160 may also be provided with an exhaust device.

The substrate transfer robot 161 is provided in the interior of the substrate transfer chamber 160. The substrate transfer robot 161 loads the substrates W into the substrate holder WB inside the load lock chamber 120 via the loading/unloading port 120b, and also unloads the substrates W held by the substrate holder WB inside the load lock chamber 120 via the loading/unloading port 120b. The substrate transfer robot 161 may include a horizontal multi-joint arm.

The controller 190 may be a computer equipped with at least one processor 191, a memory 192, an input/output interface (not illustrated), and an electronic circuit (not illustrated). The processor 191 is a combination of one or more of a CPU, ASIC, FPGA, a circuit composed of a plurality of discrete semiconductors, and the like. The memory 192 includes a volatile memory and a non-volatile memory (such as a compact disk, DVD, hard disk, and flash memory), and stores programs for executing an operation of the substrate processing apparatus 100 and recipes such as process conditions of processing. The processor 191 executes the programs and recipes stored in the memory 192, thereby controlling each component of the substrate processing apparatus 100 to perform various types of processing.

As described above, according to the first embodiment, the lifting mechanism 121 includes the support 122 for supporting the substrate holder WB and the multi-joint arm 123, the tip of which is connected to the support 122 to raise or lower the support 122. By incorporating the multi-joint arm 123 in the lifting mechanism 121, the mechanical components for raising or lowering the substrate holder WB may be arranged in the internal space hermetically isolated from the internal atmosphere of the load lock chamber 120. This may suppress the generation of dust when raising or lowering the substrate holder WB. The multi-joint arm 123 is accommodated in and operates inside the load lock chamber 120, which makes it possible to reduce an operating range of the multi-joint arm 123. This achieves space savings. For example, by reducing a height of the load lock chamber 120, a height of the processing chamber 110 may be increased while maintaining a height of the substrate processing apparatus 100. In this case, the number of substrates W to be collectively processed may be increased, which improves productivity. Further, by increasing a pitch between adjacent substrates W, it is possible to improve thermal uniformity and processing uniformity. As described above, according to the first embodiment, both the dust reduction and the space savings may be achieved.

In contrast, for example, in a case in which the substrate holder WB is raised or lowered by a ball screw, scattering of lubricants used in sliding components and outgassing from the lubricants may occur. For example, in a case in which a shaft that penetrates a bottom wall of the load lock chamber 120 is provided and the substrate holder WB is connected to an upper end of the shaft, a space is required beneath the load lock chamber 120 to ensure the movement of the shaft when raising or lowering the substrate holder WB.

In the first embodiment, an example in which the multi-joint arm 123 includes two arms (the first arm 123b and the second arm 123c) has been described, but the number of arms constituting the multi-joint arm 123 is not limited thereto. The multi-joint arm 123 may include three or more arms.

### Second Embodiment

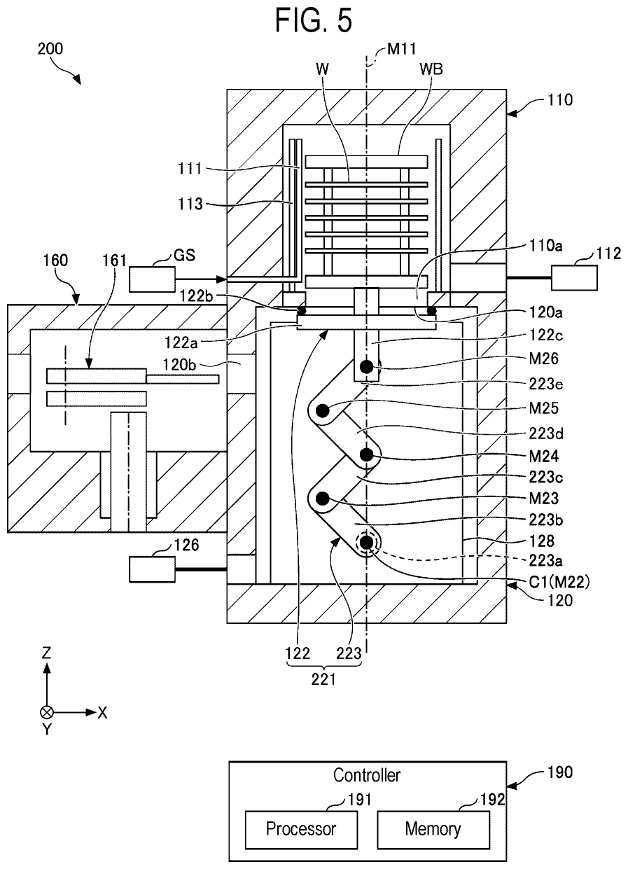

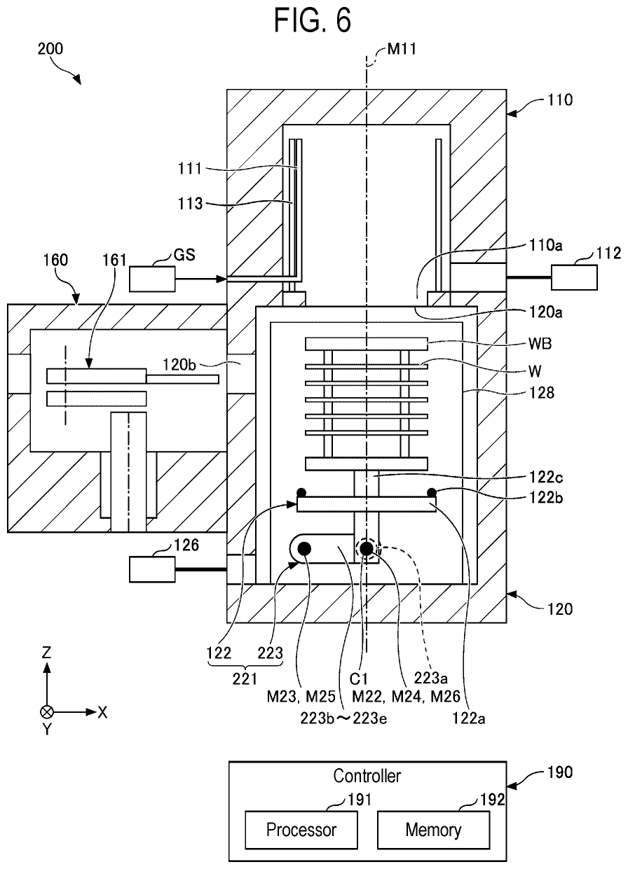

A substrate processing apparatus 200 according to a second embodiment will be described with reference to FIGS. 5 to 6. The substrate processing apparatus 200 differs from the substrate processing apparatus 100 in that it includes a multi-joint arm 223 with a pivot center located below the midpoint of the stroke. The following description will focus on differences in configuration from the substrate processing apparatus 100.

The substrate processing apparatus 200 includes the processing chamber 110, the load lock chamber 120, the substrate transfer chamber 160, and the controller 190.

The load lock chamber 120 is provided with a lifting mechanism 221, the exhaust device 126, the cooling gas supplier 127, and the exhaust duct 128.

The lifting mechanism 221 raises or lowers the substrate holder WB between the processing chamber 110 and the load lock chamber 120. The lifting mechanism 221 includes the support 122 and the multi-joint arm 223.

The multi-joint arm 223 includes a base end 223a, a first arm 223b, a second arm 223c, a third arm 223d, and a fourth arm 223e.

The base end 223a is fixed to the sidewall of the load lock chamber 120 in the positive Y-direction. The base end 223a may be positioned below the midpoint of the stroke of the multi-joint arm 223. In this case, since mechanical components of the multi-joint arm 223 are constantly positioned below the substrate holder WB, they are less likely to receive radiant heat from the substrates W. The first arm 223b is rotatable relative to the base end 223a about a rotation axis M22. The second arm 223c is rotatable relative to the first arm 223b about a rotation axis M23. The third arm 223d is rotatable relative to the second arm 223c about a rotation axis M24. The fourth arm 223e is rotatable relative to the third arm 223d about a rotation axis M25 and is also rotatable relative to the support arm 122d about a rotation axis M26. The multi-joint arm 223 raises or lowers the substrate holder WB between a position inside the processing chamber 110 (FIG. 5) and a position inside the load lock chamber 120 (FIG. 6) by rotating the first arm 223b, the second arm 223c, the third arm 223d, and the fourth arm 223e independently of each other.

The multi-joint arm 223 may have an internal space hermetically isolated from the internal atmosphere of the load lock chamber 120 by a magnetic fluid seal or the like. In this case, mechanical components of the multi-joint arm 223 may be arranged in the internal space hermetically isolated from the internal atmosphere of the load lock chamber 120. This may suppress the generation of dust when raising or lowering the substrate holder WB. The internal space of the multi-joint arm 223 may accommodate a plurality of motors equipped with deceleration gears and cables for driving the motors. These motors equipped with the deceleration gears rotate the arms of the multi-joint arm 223 independently of each other. The internal space of the multi-joint arm 223 may be set to atmospheric pressure.

As described above, according to the second embodiment, the lifting mechanism 221 includes the support 122 for supporting the substrate holder WB and the multi-joint arm 223, the tip of which is connected to the support 122 to raise or lower the support 122. In this case, the same effects as those in the first embodiment are obtained.

In the second embodiment, an example in which the multi-joint arm 223 includes four arms (the first arm 223b, the second arm 223c, the third arm 223d, and the fourth arm 223e) has been described, but the number of arms constituting the multi-joint arm 223 is not limited thereto. The multi-joint arm 223 may include three or fewer arms, or may include five or more arms.

### Third Embodiment

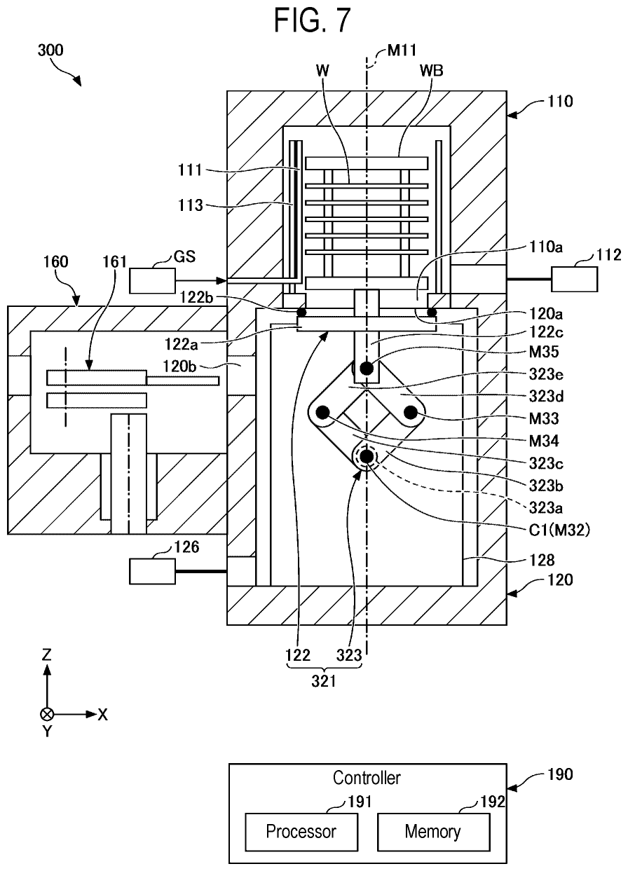

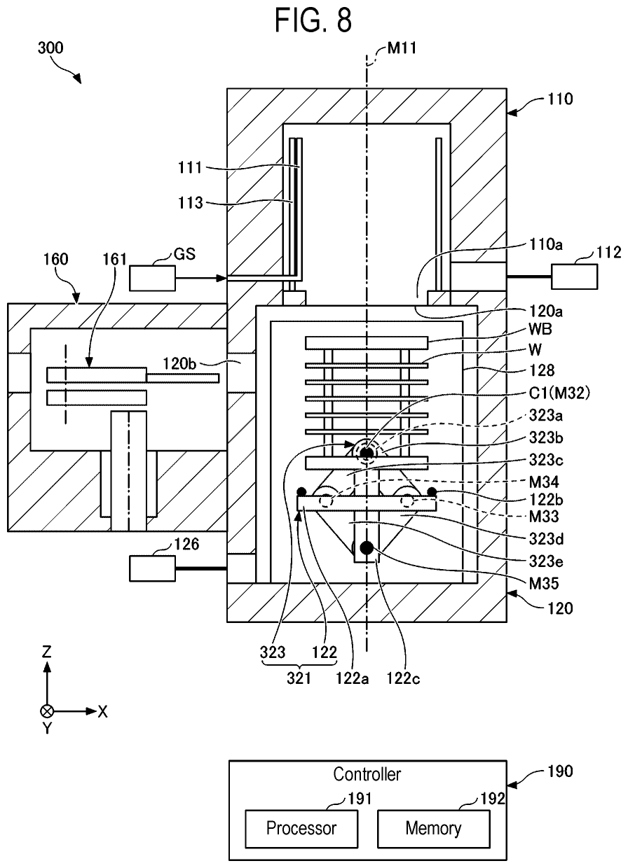

A substrate processing apparatus 300 according to a third embodiment will be described with reference to FIGS. 7 and 8. The substrate processing apparatus 300 differs from the substrate processing apparatus 100 in that it includes a frog-leg-type multi-joint arm 323 in which arms are arranged symmetrically with respect to a vertical trajectory line of the center of gravity of the substrate holder WB. The following description will focus on differences in configuration from the substrate processing apparatus 100.

The substrate processing apparatus 300 includes the processing chamber 110, the load lock chamber 120, the substrate transfer chamber 160, and the controller 190.

The load lock chamber 120 is provided with a lifting mechanism 321, the exhaust device 126, the cooling gas supplier 127, and the exhaust duct 128.

The lifting mechanism 321 raises or lowers the substrate holder WB between the processing chamber 110 and the load lock chamber 120. The lifting mechanism 321 includes the support 122 and the multi-joint arm 323.

The multi-joint arm 323 is a frog-leg-type vertical multi-joint arm in which arms are arranged symmetrically with respect to the vertical trajectory line of the center of gravity of the substrate holder WB. In this case, a load torque applied to each joint of the multi-joint arm 323 is halved, which achieves a reduction in size of the arm and an improvement in precision. The vertical trajectory line of the center of gravity of the substrate holder WB may be equal to the vertical axis M11. The multi-joint arm 323 includes a base end 323a, a first arm 323b, a second arm 323c, a third arm 323d, and a fourth arm 323e.

The base end 323a is fixed to the sidewall of the load lock chamber 120 in the positive Y-direction. The base end 323a may be positioned at the midpoint of the stroke of the multi-joint arm 323. In this case, the length of each of the arms constituting the multi-joint arm 323 and the number of arms may be minimized. Each of the first arm 323b and the second arm 323c is rotatable relative to the base end 323a about a rotation axis M32. The third arm 323d is rotatable relative to the second arm 323c about a rotation axis M33 and is also rotatable relative to the support arm 122d about a rotation axis M35. The fourth arm 323e is rotatable relative to the third arm 323d about a rotation axis M34 and is also rotatable relative to the support arm 122d about the rotation axis M35. The multi-joint arm 323 raises or lowers the substrate holder WB between a position inside the processing chamber 110 (FIG. 7) and a position inside the load lock chamber 120 (FIG. 8) by rotating the first arm 323b, the second arm 323c, the third arm 323d, and the fourth arm 323e independently of each other.

The multi-joint arm 323 may have an internal space hermetically isolated from the internal atmosphere of the load lock chamber 120 by a magnetic fluid seal or the like. In this case, mechanical components of the multi-joint arm 323 may be arranged in the internal space hermetically isolated from the internal atmosphere of the load lock chamber 120. This may suppress the generation of dust when raising or lowering the substrate holder WB. The internal space of the multi-joint arm 323 may accommodate a plurality of motors equipped with deceleration gears and cables for driving the motors. These motors equipped with the deceleration gears rotate the arms of the multi-joint arm 323 independently of each other. The internal space of the multi-joint arm 323 may be set to atmospheric pressure.

As described above, according to the third embodiment, the lifting mechanism 321 includes the support 122 for supporting the substrate holder WB and the multi-joint arm 323, the tip of which is connected to the support 122 to raise or lower the support 122. In this case, the same effects as those in the first embodiment are obtained.

In the third embodiment, an example in which the multi-joint arm 323 includes four arms (the first arm 323b, the second arm 323c, the third arm 323d, and the fourth arm 323e) has been described, but the number of arms constituting the multi-joint arm 323 is not limited thereto. The multi-joint arm 323 may include six or more arms.

According to the present disclosure, it is possible to achieve both dust reduction and space savings.

The embodiments disclosed herein should be considered illustrative in all respects and not restrictive. The above embodiments may be omitted, replaced, or modified in various ways without departing from the scope and spirit of the appended claims.

What is claimed is:

1. A lifting mechanism for raising or lowering a substrate holder configured to hold a plurality of substrates in a shelf-like manner, the lifting mechanism comprising:
a support configured to support the substrate holder; and
a multi-joint arm having a tip connected to the support to raise or lower the support.

2. The lifting mechanism of claim 1, wherein the support includes a rotary shaft configured to rotate the substrate holder around a vertical axis.

3. The lifting mechanism of claim 1, wherein the multi-joint arm includes an internal coolant flow path.

4. A substrate processing apparatus comprising:
a processing chamber configured to collectively process a plurality of substrates held by a substrate holder;
a load lock chamber located below the processing chamber and in communication with the processing chamber; and
a lifting mechanism configured to raise or lower the substrate holder between the processing chamber and the load lock chamber,
wherein the lifting mechanism includes:
a support configured to support the substrate holder; and
a multi-joint arm having a tip connected to the support to raise or lower the support.

5. The substrate processing apparatus of claim 4, wherein the support includes a rotary shaft configured to rotate the substrate holder around a vertical axis.

6. The substrate processing apparatus of claim 4, wherein the multi-joint arm includes an internal coolant flow path.

7. The substrate processing apparatus of claim 4, wherein the load lock chamber is capable of being depressurized.

8. The substrate processing apparatus of claim 4, wherein the support includes a lid configured to hermetically seal the processing chamber in a state in which the substrate holder is positioned inside the processing chamber.

9. The substrate processing apparatus of claim 4, wherein the multi-joint arm includes a base fixed to a first sidewall of the load lock chamber.

10. The substrate processing apparatus of claim 9, further comprising:
an exhaust duct provided on the first sidewall of the load lock chamber; and
a cooling gas supplier provided on a second sidewall facing the first sidewall and configured to discharge a cooling gas,
wherein the exhaust duct is provided on an entire surface of the first sidewall except a position where the base of the multi-joint arm is fixed.

11. The substrate processing apparatus of claim 4, wherein a pivot center of the multi-joint arm is located below a midpoint of a stroke of the multi-joint arm.

12. The substrate processing apparatus of claim 4, wherein a pivot center of the multi-joint arm is located at a midpoint of a stroke of the multi-joint arm.
